(19) United States
(12) Patent Application Publication
(10) Pub. No.: US 2008/0227297 A1
(43) Pub. Date: Sep. 18, 2008

(54) CHEMICAL MECHANICAL POLISHING METHOD AND METHOD FOR MANUFACTURING SEMICONDUCTOR DEVICE

(76) Inventors: Yukiteru MATSUI, Yokohama-shi (JP); Gaku Minamihaba, Yokohama-shi (JP); Takeshi Nishioka, Yokohama-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/038,877

(22) Filed: Feb. 28, 2008

(30) Foreign Application Priority Data
Mar. 16, 2007 (JP) 2007-069170

(51) Int. Cl. H01L 21/304; B24B 29/02

(52) U.S. Cl. 438/693; 451/37; 451/59; 257/E21.237

(57) ABSTRACT

A chemically mechanically polishing method is provided, which includes slide-contacting a polishing film with a polishing pad while feeding a first chemical liquid and a second chemical liquid to the polishing pad. The first chemical liquid contains an electrolyte and bubbles having a diameter ranging from 10 nm to 1000 μm, and the second chemical liquid contains abrasive particles.

### CROSS-REFERENCE TO RELATED APPLICATIONS

This application is based upon and claims the benefit of priority from prior Japanese Patent Application No. 2007-069170, filed Mar. 16, 2007, the entire contents of which are incorporated herein by reference.

### BACKGROUND OF THE INVENTION

1. Field of the Invention

This invention relates to a chemically mechanically polishing method and to a method for manufacturing a semiconductor device.

2. Description of the Related Art

In recent years, it is demanded in the manufacture of a semiconductor integrated circuit device that the surface of semiconductor substrate to be treated be excellent in planarity such that the roughness thereof is limited to the order of several tens of nanometers in order to inhibit the deterioration in depth of focus in the step of lithography, which deterioration may occur because of recent trends to further promote the fineness of circuit patterns.

As the methods for realizing such an excellent planarity as mentioned above, a chemically mechanically polishing method has been mainly employed. For example, many efforts are now actively made for the development of a CMP (Chemical Mechanical Polishing) technique for an SiO₂ film to be employed for forming an element isolation region (STI: Shallow Trench Isolation) or for the development of a CMP technique for a metallic film such as a Cu film or a W film to be employed for forming so-called damascene wirings.

In these CMP techniques, the polishing of a semiconductor substrate is performed by slide-contacting the semiconductor substrate (wafer), which is sustained by a carrier with a polishing pad adhered to a polishing table, while feeding a slurry to an interface between the polishing pad and the semiconductor substrate. However, these CMP techniques are accompanied with various problems that need to be overcome.

For example, it is demanded to reduce the friction generated between the polishing pad and the wafer during the CMP. Especially, in the case of the CMP of a Cu film, due to the poor adhesion between the Cu film and a low relative dielectric constant film constituting an insulating film, the Cu film tends to be easily peeled off, thus leading to the decrease in yields of wirings.

In a case where a slurry containing abrasive particles is employed in the polishing, there are problems as explained below. Coarse particles in the abrasive particles may become a cause for generating scratches on the surface of the film to be polished (hereinafter referred to as a polishing film), thus giving rise to one of the causes for decreasing the yields of wirings. Generally, so-called dressing of the surface of a polishing pad is performed on the surface of a polishing pad in order to enhance the retainability of abrasive particles to the polishing pad. As a result of the dressing, the roughness of the surface of the polishing pad may become as large as several tens of micrometers, which is far larger than the size of abrasive particles (several hundreds nanometers). For this reason, it is no longer possible to enable the abrasive particles to effectively act on the polishing film, resulting in a decrease in the polishing rate and hence in the deterioration of productivity.

As one of the means for solving these problems, U.S. Pat. No. 6,740,590 discloses a method wherein resin particles are included in a slurry. However, this method is accompanied with problems that since the resin particles are an organic matter, the environmental load for the disposal of waste liquid becomes heavy, thus leading to great rise in running cost. In comparison with the aforementioned method, a chemically mechanically polishing method wherein a polishing liquid containing bubbles is employed is proposed in JP-A 2006-114861 (KOKAI). In this case, a polishing liquid containing bubbles in addition to abrasive particles is employed so as to increase the actual contact area between the polishing pad and a semiconductor wafer. However, there are increasingly severe demands with regard to the performance of CMP.

### BRIEF SUMMARY OF THE INVENTION

A chemically mechanically polishing method according to one aspect of the present invention comprises slide-contacting a polishing film with a polishing pad while feeding a first chemical liquid and a second chemical liquid to the polishing pad, the first chemical liquid containing an electrolyte and bubbles having a diameter ranging from 10 nm to 1000 μm, and the second chemical liquid containing abrasive particles.

A method for manufacturing a semiconductor device according to one aspect of the present invention comprises forming a polishing film above a semiconductor substrate; and slide-contacting the polishing film with a polishing pad while feeding a first chemical liquid and a second chemical liquid to the polishing pad, thereby chemically mechanically polishing the polishing film, the first chemical liquid containing an electrolyte and bubbles having a diameter ranging from 10 nm to 1000 μm, the second chemical liquid containing abrasive particles.

### BRIEF DESCRIPTION OF THE SEVERAL VIEWS OF THE DRAWING

FIG. 1 shows a diagram schematically explaining the a chemically mechanically polishing method according to one embodiment;

FIG. 2 is a diagram illustrating a state of bubbles;

FIG. 3 is a diagram illustrating a state of the chemical mechanical polishing according to one embodiment;

FIG. 4 is a diagram illustrating a state of the chemical mechanical polishing according to the prior art; and

FIG. 5 is a diagram schematically explaining the chemically mechanically polishing method according to another embodiment.

### DETAILED DESCRIPTION OF THE INVENTION

Next, embodiments of the present invention will be explained with reference to drawings.

Incidentally, the present invention should not be construed as being limited to the following embodiments but should be understood to include various modified embodiments that can be carried out without departing from the spirit of the present invention.

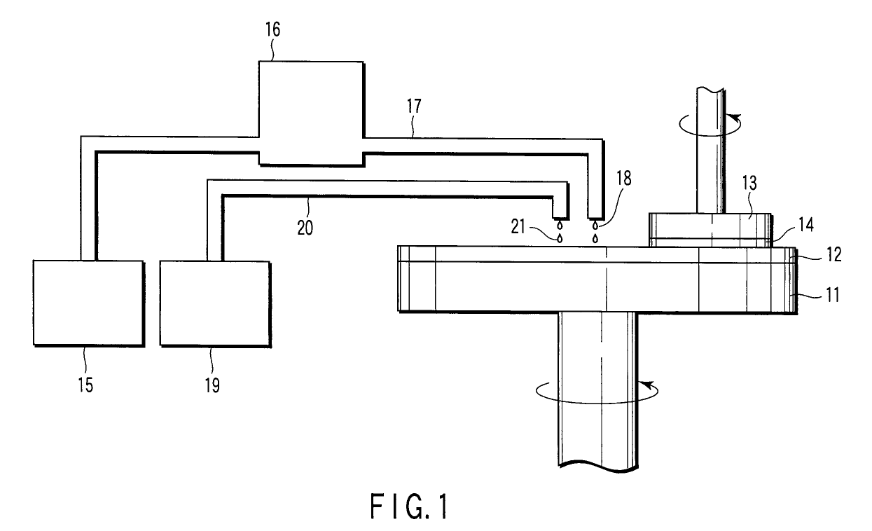

The chemically mechanically polishing method according to one embodiment of the present invention will be explained with reference to FIG. 1. As shown in FIG. 1, a semiconductor substrate 14 held by a polishing head 13 is contacted with a polishing pad 12 which is adhered onto a polishing table 11. A slurry is fed to the polishing pad 12 and the polishing table 11 as well as the polishing head 13 is rotated at a predetermined rotational speed, whereby a polishing film (not shown) formed on the semiconductor substrate 14 is polished.

The slurry to be employed in the polishing of the polishing film is constituted by a specific first chemical liquid 18 and a specific second chemical liquid 21. The first chemical liquid 18 contains an electrolyte and bubbles (microbubbles) having a diameter ranging from 10 nm to 1000 μm and acts as an additive for inhibiting the generation of defects as well as for promoting the polishing of the polishing film during the polishing process. On the other hand, the second chemical liquid 21 contains abrasive particles and polishes the polishing film.

The first chemical liquid 18 can be prepared by enabling the electrolyte solution to generate bubbles. In the embodiment shown in FIG. 1, a solution containing an electrolyte is placed in an electrolyte solution tank 15 and then treated so as to generate bubbles by a bubble generator 16, thus obtaining the first chemical liquid 18. The first chemical liquid 18 containing bubbles is fed, via a first chemical liquid nozzle 17, to the polishing pad 12.

As the electrolyte, it is possible to employ, for example, calcium, magnesium, iron, etc. Among them, it is preferable to employ a substance which does not badly affect the electric properties of semiconductor element. More specifically, a component which has been confirmed to be actually useful as one of the components of a CMP slurry, e.g. a component selected from an oxidizing agent, an oxidation inhibitor, a surfactant and a pH adjustor can be employed as the electrolyte.

As the oxidizing agent, it is possible to employ, for example, ammonium persulfate, hydrogen peroxide, iron nitrate, etc. As the oxidation inhibitor, it is possible to employ, for example, quinaldinic acid, quinolinic acid, benzotriazole, etc.

As the surfactant, it is possible to employ an anionic surfactant such as dodecylbenzenesulfonic acid, etc.; a cationic surfactant such as lauryl trimethyl ammonium chloride, etc.; and a nonionic surfactant such as acetylene diol, etc. Alternatively, it is also possible to employ, as a surfactant, celluloses such as methyl cellulose, methyl hydroxyethyl cellulose, methyl hydroxypropyl cellulose, hydroxyethyl cellulose, hydroxypropyl cellulose, carboxymethyl cellulose, carboxyethyl cellulose, carboxymethyl hydroxyethyl cellulose, etc.; polysaccharides such as chitosan, etc.; and water-soluble polymers such as polyethylene glycol, polyethylene imine, polyvinylpyrrolidone, polyvinyl alcohol, polyacrylic acid and salts thereof, polyacryl amide, polyethylene oxide, etc.

Further, as the pH adjustor, it is possible to employ, for example, inorganic acids such as nitric acid, hydrochloric acid, phosphoric acid, etc.; organic acids such as formic acid, malonic acid, maleic acid, citric acid, etc.; ammonia; potassium hydroxide; etc.

The electrolytes described above are effective in stabilizing the bubbles to prolong the life of the bubbles. As long as the electrolyte is dissolved in the first chemical liquid in a manner to secure an electric conductivity of 3 mS/cm or more, it is possible to secure desirable effects of the electrolyte.

In the bubble generator 16, bubbles are enabled to generate by an optional mechanism. As examples of this mechanism, it is possible to employ, for example, a crashing method using shock waves, a crashing method utilizing cavitation, a supersaturating separation method utilizing pressure dissolution, a turbulent flow method, a micropore method, a solid embedding method, an electrolysis method, a chemical reaction method, a reduction method, etc. Examples of the bubble generator useful in this case include an apparatus available in the market such as a pressure dissolution pump, a compression type pressure device, a nozzle device, an injection device, a rotary stirrer, a whirling flow type device, etc.

Using these devices, it is possible to generate bubbles having a diameter ranging from 10 nm to 1000 μm. It is difficult to create bubbles smaller than the aforementioned lower limit. On the other hand, the bubbles larger than the aforementioned upper limit are accompanied with the problem that since the buoyancy thereof increases as the size of bubbles becomes larger, the rising velocity thereof up to the surface of water is increased, thus shortening the life of the bubbles. The diameter of bubbles can be measured, for example, by a submerged particle counter. Alternatively, the diameter of bubbles can be measured by picture processing using an optical microscope and a video camera. When the diameter of bubbles is confined to be not more than several micrometers, it is also possible to employ a laser diffraction method or a scattering method.

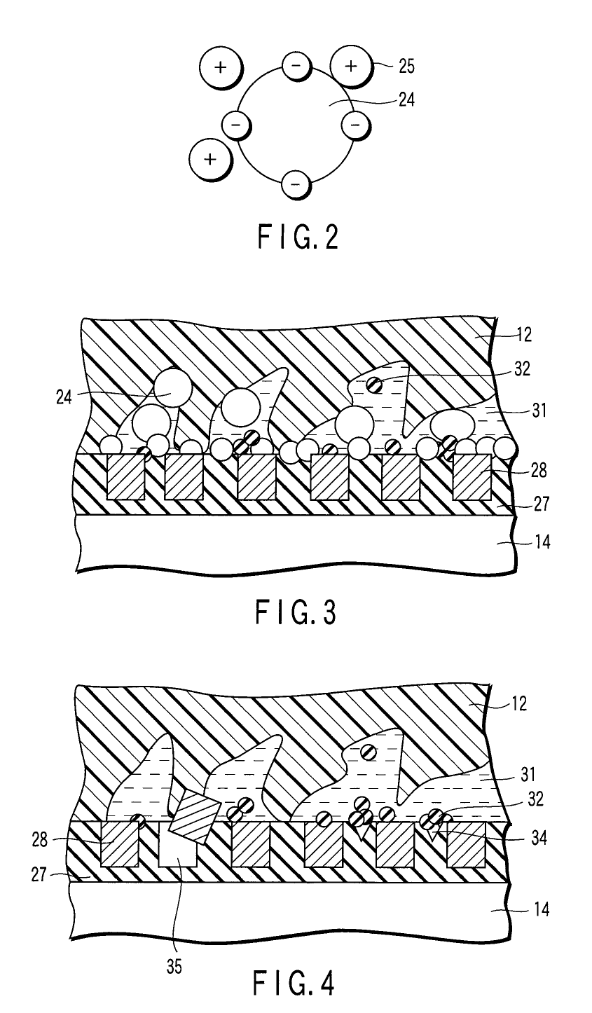

Since the bubbles are contained in the first chemical liquid together with the electrolyte, the bubbles are enabled to stably exist in the first chemical liquid. FIG. 2 schematically illustrates the state of bubbles in the first chemical liquid. As shown in FIG. 2, at the surface of bubbles 24, most of the water molecules are situated such that the oxygen atom thereof is orientated to face the gas of bubbles and hence the gas-liquid interface is negatively charged. This negative electric charge however is neutralized by the positively charged ion 25 originating from the electrolyte to form an electric double layer, thereby making it possible to keep the balance of the gas-liquid interface. In the case where the first chemical liquid contains no electrolyte and is constituted by only pure water, this positively charged ion 25 does not exist in the first chemical liquid. As a result, the bubbles 24 can not stably exist in the first chemical liquid, thus allowing the bubbles 24 to vanish within several seconds.

In order to generate bubbles in a chemical liquid as described above, a pressure is generally applied to the chemical liquid. When a pressure is applied to a chemical liquid containing abrasive particles so as to generate bubbles therein, the abrasive particles aggregate due to the application of high pressure, thus generating coarse particles. It has been confirmed by the present inventors that nearly all kinds of abrasive particles including silica form coarse particles due to the application of pressures to the chemical liquid as described above.

Incidentally, some kinds of abrasive particles may inherently contain coarse particles having a large size. However, due to the cushioning effect of bubbles as described hereinafter, the generation of scratches can be suppressed. However, the particle diameter of the aggregated coarse particles that have been formed due to the application of pressure would be far larger than that of the coarse particles that inherently exist in the abrasive particles. Therefore, it is no longer possible to enable the bubbles to act as a cushion, thus leading to the increase in generation of scratches on the surface of polishing film during the polishing.

Further, when the abrasive particles coexist together with the bubbles, the abrasive particles adsorb on the surface of bubbles and repeated adsorption of abrasive particles on the surface of bubbles may result in the coalescence of bubbles. The bubbles thus increased in diameter would increase the probability of vanishing through the rising of bubbles up to the surface of water. For example, due to the fact that, in the case of abrasive particles made of alumina or ceria, the zeta potential is accompanied with a positive electric charge and due to the fact that, in the case of resin particles, the surface thereof is hydrophobic, the aforementioned phenomenon is more likely to take place. As described above, if a substance whose surface is hydrophobic or a substance where the zeta potential thereof is accompanied with a positive electric charge is employed as abrasive particles, it would be impossible to enable the bubbles to stably exist in the presence of abrasive particles.

In order to prevent the aggregation of abrasive particles or the vanishing of bubbles, the embodiment of the present invention is formulated such that abrasive particles are not incorporated into a first chemical liquid containing bubbles but incorporated into a second chemical liquid which is supplied separately from the first chemical liquid.

As shown in FIG. 1, the second chemical liquid 21 containing abrasive particles is fed from a second chemical liquid tank 19 via a second chemical liquid nozzle 20 to the polishing pad 12. As the abrasive particles, it is possible to employ inorganic particles such as colloidal silica, fumed silica, ceria, alumina, titanium oxide, zirconia, manganese dioxide, etc.; or organic particles such as polystyrene, poly(methylmethacrylate), etc. These inorganic particles may be employed together with these organic particles.

The abrasive particles can be suitably selected depending on the kinds of polishing film (film to be polished). Generally, the abrasive particles are dispersed in water at a concentration ranging from about 0.001 to 10 wt % to prepare the second chemical liquid. Further, depending on the kinds of polishing film, the second chemical liquid 21 may further contain at least one selected from an oxidizing agent, an oxidation inhibitor, a surfactant and a pH adjustor. The polishing film may be formed of, for example, a metal selected from a group consisting of Cu, Al, W, Ti, Mo, Nb, Ta, V and Ru; or formed of a laminate film comprising the metal. Alternately, the polishing film may be a film formed of an alloy containing, as a major component, the metal or formed of a nitride, boride or oxide of the metal. Further, the polishing film may be constituted by an SiO₂-based insulating film or an organic film. These polishing films can be formed, directly or through an underlying layer having a recess, above the semiconductor substrate.

For example, when it is desired to polish a metallic film such as a Cu film, a W film, etc., it is possible to employ colloidal silica, alumina, etc. as abrasive particles. In addition to the abrasive particles, the second chemical liquid may contain at least one selected from, for example, an oxidizing agent, an oxidation inhibitor and a surfactant. The concentration of any of these components is generally confined to about 0.001 to 10 wt %.

When an insulating film such as an SiO₂ film is polished, it is possible to employ ceria as abrasive particles. When an organic film such a resist film is polished, it is possible to employ organic particles as abrasive particles. The second chemical liquid may contain about 0.001-10 wt % of surfactant.

Further, when it is desired to polish a metallic film such as a Cu film, a W film, etc., the second chemical liquid may contain about 0.001-10 wt % of a pH adjustor.

As examples of the oxidizing agent, the oxidation inhibitor, the surfactant and the pH adjustor, it is possible to employ the same kinds of materials which are enumerated as being includable in the first chemical liquid.

As shown in FIG. 1, the first chemical liquid 18 and the second chemical liquid 21 are both fed to the polishing pad 12, thereby enabling slurry (not shown) to be prepared right on this polishing pad 12. Using the slurry thus prepared, the polishing film formed on the semiconductor substrate 14 is slide-contacted with the polishing pad 12, thereby making it possible to polish the polishing film.

Next, the state in which the chemical mechanical polishing is carried out according to this embodiment will be explained by referring to the bubbles and abrasive particles existing in the slurry and with reference to FIG. 3.

As shown in FIG. 3, an insulating film 27 having a trench pattern is deposited on the semiconductor substrate 14 and the trench patterns are respectively filled with a polishing film 28 by chemical mechanical polishing using the slurry. The polishing film 28 in this case can be formed from a metallic film or a resist film. Water 31, abrasive particles 32 and bubbles 24, which are all components of slurry, interpose between the polishing pad 12 and the polishing film 28.

Since an electrolyte (not shown) is included in the slurry, it is possible, as described above, to enable the bubbles 24 to stably exist in the slurry. Due to the stability of the bubbles 24, it is possible to obtain various effects. For example, since the bubbles 24 are enabled to interpose between the surface of polishing pad 12 and the coarse particles (not shown), the bubbles excellent in elasticity are enabled to act just like a cushion. As a result, it is now possible to prevent the generation of scratches on the polishing surface that may be otherwise caused by coarse particles. The problem of the generation of scratches mentioned above has been conventionally considered difficult to avoid.

Further, since the abrasive particles adsorb on the peripheries of bubbles having relatively large size, the diameter of abrasive particles increase substantially. Because of this, it is now possible to enable abrasive particles to effectively act on the polishing surface while preventing the abrasive particles from being buried in the surface roughness of polishing pad as conventionally caused to occur. As a result, it is possible to increase the polishing rate and hence to improve the productivity.

Additionally, since bubbles are contained in the slurry, the concentration of oxygen in water can be increased, resulting in increased activation of microorganisms, thus minimizing the burden of waste liquid on the environment. Further, since a bubble generator is installed in the CMP apparatus, an additional slurry material such as additives need not be employed, thus making it possible to reduce the cost for the slurry and hence to realize a process of low running cost.

In particular, when a low dielectric constant film is employed as the insulating film 27 and a Cu film is employed as the polishing film 28, it is possible to achieve the effect of preventing the peeling of the film. As examples of the low dielectric constant film, there are known various kinds of film, including polyaryl ether (Allied Signals Co., Ltd.(trade name: FLARE); SiLK (trade name, Dow Chemicals Co., Ltd.), benzocyclobutene (Dow Chemicals Co., Ltd.), polyimide, Coral (trade name, Novelas Co., Ltd.), Aurora (trade name, ASM Co., Ltd.), Black Diamond (trade name, Applied Materials Co., Ltd.), LKD (trade name, JSR Co., Ltd.), and methylsilsesquioxane. Since a Cu film is low in adhesion to these low dielectric constant films, the peeling of film 35 has been occurred as shown in FIG. 4 due to the friction during the polishing according to the prior art. Further, since the low dielectric constant film is brittle, scratches 34 have been occasionally generate as shown in FIG. 4.

In the case of this embodiment, since the slurry comprising an electrolyte and bubbles as described above is fed to the polishing pad, the bubbles having a hydrophobic surface adsorb on the surface of low dielectric constant film which is also hydrophobic. The density of the gas is as low as about 1/1000 of that of water, so that when the bubbles are accumulated in the vicinity of this low dielectric constant film, the friction caused by the abrasive particles is reduced by the accumulated bubbles. As a result, the peeling of film or the generation of scratches can be inhibited.

As described above, according to the embodiment of the present invention, due to the existence of bubbles in the slurry, it is possible to obtain various effects such as the reduction of friction during the polishing. In order to enable these effects of bubbles to be sufficiently exhibited, it is desirable to isolate the bubbles from any component that may become a cause for bringing about the vanishing of bubbles. Therefore, as shown in FIG. 1, the first chemical liquid 18 containing bubbles should preferably be fed to the polishing pad 12 through a route which is provided separately from that of the second chemical liquid 21 containing abrasive particles. In this case, the flow rate of the first chemical liquid 18 may be confined to about 1-1000 mL/min and the flow rate of the second chemical liquid 21 may be confined to about 1-1000 mL/min. However, when the flow rate of the first chemical liquid 18 is too large, the ratio in flow rate of the second chemical liquid 21 based on a total flow of slurry may become too small, thus possibly badly affecting the polishing performance of the slurry. Therefore, the flow rate of the first chemical liquid 18 should preferably be as small as possible with a proviso that the effects of bubbles can be sufficiently exhibited.

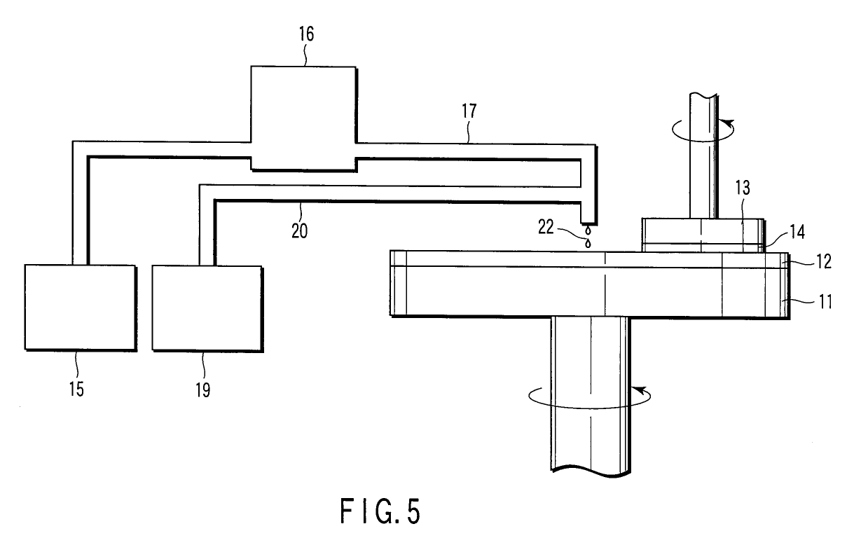

If it is possible to prevent the life of bubbles from being damaged, a distal end of the first chemical liquid nozzle 17 may be connected with a distal end of the second chemical liquid nozzle 20 as shown in FIG. 5. In this case, a slurry 22 consisting of a mixture comprising the first chemical liquid and the second chemical liquid is directly fed to the polishing pad 12. Since bubbles are included in this slurry 22, it is possible to achieve the desirable effects as described above.

Next, examples of the present invention will be explained.

### EXAMPLE 1

This example explains about the CMP of SiO₂ film.

Water having micro-bubbles formed by super saturation method was prepared. First of all, 2 mL of water containing an electrolyte such as magnesium, sodium, etc. was prepared and introduced into a syringe. Then, 6 mL of air was introduced into the syringe and pressure was applied to the piston to compress this air into a volume of 2 mL, thereby allowing the air to dissolve in the water. Then, the piston was pulled up so as to increase the air space up to 6 mL to reduce the pressure inside the syringe, thus creating a super saturation state. Then, the syringe was vigorously vibrated to allow the air in a super saturation state to separate out, thus generating cloudy bubbles. The aforementioned procedures were repeated to obtain 20 mL in total of bubbles.

When the diameter of each of the bubbles was measured by picture processing method, it was about 500 μm. The stabilized state of these bubbles was confirmed by photographing using a digital camera. The stabilized state of these bubbles was also confirmed by visual observation.

Then, cerium oxide (HS-DLS2 (trade name); Hitachi Kasei Industries Ltd.) to be used as abrasive particles was dispersed at a concentration of 0.5 wt % in pure water to prepare a second chemical liquid.

As the polishing film (film to be polished), an SiO₂ film having a thickness of 1 μm and formed on the silicon substrate was prepared. As the CMP apparatus, EPO-112 (trade name, EBARA CORPORATION) was employed. As the polishing pad, IC1000/Suba 400 (Nitta Haas Co., Ltd.) was employed. The SiO₂ film was polished while feeding the first chemical liquid and the second chemical liquid to the polishing pad under the following conditions.

Flow rate of the first chemical liquid: 20 mL/min

Flow rate of the second chemical liquid: 190 mL/min

Polishing load: 400 hPa

Rotational speed of table: 100 rpm

Rotational speed of top ring: 107 rpm

The friction generated on this occasion between the polishing pad and the wafer was monitored by a table torque current. As a result, the value of the table current was about 9.3 A and the polishing rate was about 438 nm/min. Further, it was confirmed that the number of scratches was 1/wafer or less. Although the generation of scratches was assessed by a dark field image obtained from an optical microscope in this example, it is also possible to employ a defective inspecting apparatus (PUMA (trade name); KLA Tencol Co., Ltd.).

### COMPARATIVE EXAMPLE 1

The polishing of SiO₂ film was performed under the same conditions as described in Example 1 except that water containing no bubble was employed as the first chemical liquid.

When the table current was measured, it was about 9.8 A. It will be recognized that the friction during the polishing was increased as compared with that of Example 1. Incidentally, the magnitude of increase in friction during the polishing in comparison with Example 1 was increased further as the rotational speed of table was further lowered, e.g. down to 50 rpm and to 30 rpm. The polishing rate was about 400 nm/min or less and the number of scratches was more than 5/wafer. As described above, all results thus obtained were inferior to those of Example 1.

Further, the preparation of the first chemical liquid was tried in the same manner as in the case of Example 1 except that pure water containing no electrolyte was employed. Although it was tried to create bubbles by the super saturation method, it was impossible to stably generate bubbles and bubbles generated instantaneously vanished. It was confirmed that, unless an electrolyte was included in the first chemical liquid, it was impossible to obtain the first chemical liquid containing bubbles.

### EXAMPLE 2

This example explains about the CMP of a Cu film.

As the electrolyte to be contained in the first chemical liquid, a pH adjustor was employed. Specifically, potassium hydroxide was dissolved in pure water to prepare a 0.1 wt % potassium hydroxide solution. Bubbles were generated in the same manner as in Example 1 except that a solution of a pH adjustor thus obtained was employed, thus obtaining the first chemical liquid.

When the diameter of bubbles was measured by a picture processing method, it was about 10 μm. The stabilized state of these bubbles was confirmed by photographing using a digital camera.

Then, colloidal silica as abrasive particles, ammonium persulfate as an oxidizing agent, quinaldinic acid as an oxidation inhibitor and dodecylbenzene sulfonic acid as a surfactant were dissolved in pure water to prepare the second chemical liquid containing 0.5 wt % of colloidal silica, 0.1 wt % of ammonium persulfate, 0.1 wt % of quinaldinic acid and 0.1 wt % of dodecylbenzene sulfonic acid.

LKD (JSR Co., Ltd.) was deposited as a low dielectric constant film on the semiconductor substrate and then a trench pattern having a width ranging from 0.05-50 μm was formed. Thereafter, a Cu film was deposited all over the surface of the semiconductor substrate to obtain a polishing film. Using the same kind of CMP apparatus and the same kind of polishing pad as those employed in Example 1, the Cu film was polished under the following conditions.

Flow rate of the first chemical liquid: 50 mL/min

Flow rate of the second chemical liquid: 250 mL/min

Polishing load: 300 hPa

Rotational speed of table: 120 rpm

Rotational speed of top ring: 100 rpm

The friction generated on this occasion between the polishing pad and the wafer was monitored by a table torque current. As a result, the value of table current was about 10 A and the polishing rate was about 1200 nm/min. As a result of measurement using an optical microscope, it was confirmed that the number of scratches was 1/wafer or less.

### COMPARATIVE EXAMPLE 2

The polishing of a Cu film was performed under the same conditions as described in Example 2 except that the first chemical liquid was changed to an aqueous solution of a pH adjustor containing no bubbles.

When the table current was measured, it was about 12 A. It will be recognized that the friction during the polishing was increased as compared with that of Example 2. The polishing rate was about 1000 nm/min or less and the number of scratches was more than 5/wafer. As described above, all results thus obtained were inferior to those of Example 2.

Further, the first chemical liquid prepared in Comparative Example 2 was mixed with the second chemical liquid to prepare a slurry and then it was attempted to create bubbles by the super saturation method. However, it was impossible to stabilize the bubbles. The reason for this may be assumably attributed to the fact that due to action of colloidal silica included in the second chemical liquid, the vanishing of bubbles was promoted. Further, the aggregation of abrasive particles in the slurry was also confirmed.

When the polishing of the Cu film was performed by this slurry thus obtained, the number of scratches generated in the polishing was as many as 300/wafer. The reason for the increase in number of scratches up to not less than ten times as many as that of polishing using the slurry where bubbles were not included therein may be attributed to the aggregation of abrasive particles.

### EXAMPLE 3

This example explains about the CMP of the W film.

As the electrolyte to be contained in the first chemical liquid, an oxidizing agent was employed. Specifically, iron nitrate was dissolved in pure water to prepare a 0.5 wt % iron nitrate solution. Bubbles were generated in the same manner as in Example 1 except that a solution of an oxidizing agent thus obtained was employed, thus obtaining the first chemical liquid.

When the diameter of bubbles was measured by a picture processing method, it was about 80 μm. The stabilized state of these bubbles was confirmed by photographing using a digital camera.

Then, alumina as abrasive particles was dissolved at a concentration of 0.5 wt % in pure water to prepare the second chemical liquid.

SiO₂ was deposited as an insulating film on the semiconductor substrate and then a trench pattern having a width ranging from 0.05-50 μm was formed. Thereafter, a W film was deposited all over the surface of the semiconductor substrate to obtain a polishing film. Using the same kind of CMP apparatus and the same kind of polishing pad as those employed in Example 1, the W film was polished under the following conditions.

Flow rate of the first chemical liquid: 50 mL/min

Flow rate of the second chemical liquid: 200 mL/min

Polishing load: 300 hPa

Rotational speed of table: 50 rpm

Rotational speed of top ring: 53 rpm

The friction generated on this occasion between the polishing pad and the wafer was monitored by a table torque current. As a result, the value of table current was about 8 A and the polishing rate was about 350 nm/min. As a result of measurement using an optical microscope, it was confirmed that the number of scratches was 20/wafer or less.

### COMPARATIVE EXAMPLE 3

The polishing of W film was performed under the same conditions as described in Example 3 except that the first chemical liquid was changed to an aqueous solution of an oxidizing agent containing no bubbles.

When the table current was measured, it was about 9 A. It will be recognized that the friction during the polishing was increased as compared with that of Example 3. The polishing rate was about 300 nm/min or less and the number of scratches was more than 30/wafer. As described above, all results thus obtained were inferior to those of Example 3.

### EXAMPLE 4

This example explains about the CMP of an SiO₂ film.

As the electrolyte to be contained in the first chemical liquid, a surfactant was employed. Specifically, potassium dodecylbenzene sulfonate was dissolved in pure water to prepare a 0.1 wt % potassium dodecylbenzene sulfonate solution. Bubbles were generated in the same manner as in Example 1 except that a solution of surfactant thus obtained was employed, thus obtaining the first chemical liquid.

When the diameter of bubbles was measured by picture processing method, it was about 100 μm. The stabilized state of these bubbles was confirmed by photographing using a digital camera.

Then, ceria as abrasive particles was dissolved at a concentration of 0.5 wt % in pure water to prepare the second chemical liquid.

SiO₂ was deposited on the semiconductor substrate by a CVD method to obtain a polishing film. Using the same kind of CMP apparatus and the same kind of polishing pad as those employed in Example 1, the SiO₂ film was polished under the following conditions.

Flow rate of the first chemical liquid: 20 mL/min

Flow rate of the second chemical liquid: 190 mL/min

Polishing load: 300 hPa

Rotational speed of table: 100 rpm

Rotational speed of top ring: 107 rpm

The friction generated on this occasion between the polishing pad and the wafer was monitored by a table torque current. As a result, the value of the table current was about 8 A and the polishing rate was about 400 nm/min. As a result of measurement using an optical microscope, it was confirmed that the number of scratches was 1/wafer or less.

### COMPARATIVE EXAMPLE 4

The polishing of an SiO₂ film was performed under the same conditions as described in Example 4 except that the first chemical liquid was changed to an aqueous solution of a surfactant containing no bubbles.

When the table current was measured, it was about 9 A. It will be recognized that the friction during the polishing was increased as compared with that of Example 4. The polishing rate was about 380 nm/min or less and the number of scratches was more than 5/wafer. As described above, all results thus obtained were inferior to those of Example 4.

### EXAMPLE 5

This example explains about the CMP of a resist film.

As the electrolyte to be contained in the first chemical liquid, a water-soluble polymer was employed. Specifically, polyvinyl alcohol was dissolved in pure water to prepare a 0.05 wt % polyvinyl alcohol solution. Bubbles were generated in the same manner as in Example 1 except that a solution of a water-soluble polymer thus obtained was employed, thus obtaining the first chemical liquid.

When the diameter of bubbles was measured by a picture processing method, it was about 20 μm. The stabilized state of these bubbles was confirmed by photographing using a digital camera.

Then, polystyrene particles as abrasive particles and polyvinyl alcohol as a water-soluble polymer were dissolved in pure water to prepare the second chemical liquid containing 0.83 wt % of polystyrene particles and 0.1 wt % of polyvinyl alcohol.

A resist film was deposited on the semiconductor substrate by spin-coating method to obtain a polishing film. Using the same kind of CMP apparatus and the same kind of polishing pad as those employed in Example 1, the resist film was polished under the following conditions.

Flow rate of the first chemical liquid: 50 mL/min

Flow rate of the second chemical liquid: 250 mL/min

Polishing load: 100 hPa

Rotational speed of table: 30 rpm

Rotational speed of top ring: 33 rpm

The friction generated on this occasion between the polishing pad and the wafer was monitored by a table torque current. As a result, the value of the table current was about 5 A and the polishing rate was about 120 nm/min. As a result of measurement using an optical microscope, it was confirmed that the number of scratches was 2/wafer or less.

### COMPARATIVE EXAMPLE 5

The polishing of a resist film was performed under the same conditions as described in Example 5 except that the first chemical liquid was changed to an aqueous solution of a water-soluble polymer containing no bubbles.

When the table current was measured, it was about 7 A. It will be recognized that the friction during the polishing was increased as compared with that of Example 5. The polishing rate was about 100 nm/min or less and the number of scratches was more than 20/wafer. As described above, all results thus obtained were inferior to those of Example 5.

According to one aspect of the present invention, it is possible to provide a chemically mechanically polishing method which makes it possible to minimize the friction between a polishing film and a polishing pad, to reduce defects generated on the surface of polishing film in the step of polishing, to carry out the polishing of a polishing film at a high polishing rate and to minimize the environmental load for the disposal of waste liquid. According to another aspect of the present invention, it is possible to provide a method of manufacturing a semiconductor device at high yields.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A chemically mechanically polishing method comprising slide-contacting a polishing film with a polishing pad while feeding a first chemical liquid and a second chemical liquid to the polishing pad, the first chemical liquid containing an electrolyte and bubbles having a diameter ranging from 10 nm to 1000 μm, and the second chemical liquid containing abrasive particles.

2. The method according to claim 1, wherein the electrolyte contained in the first chemical liquid is selected from a group consisting of an oxidizing agent, an oxidation inhibitor, a surfactant and a pH adjustor.

3. The method according to claim 2, wherein the oxidizing agent is selected from a group consisting of ammonium persulfate, hydrogen peroxide and iron nitrate.

4. The method according to claim 2, wherein the oxidation inhibitor is selected from a group consisting of quinaldinic acid, quinolinic acid and benzotriazole.

5. The method according to claim 2, wherein the surfactant is selected from a group consisting of an anionic surfactant, a cationic surfactant, a nonionic surfactant, celluloses, polysaccharides and water-soluble polymers.

6. The method according to claim 2, wherein the pH adjustor is selected from a group consisting of nitric acid, hydrochloric acid, phosphoric acid, formic acid, malonic acid, maleic acid, citric acid, ammonia and potassium hydroxide.

7. The method according to claim 1, wherein the first chemical liquid is free from abrasive particles.

8. The method according to claim 1, wherein the abrasive particles are formed of a material selected from a group consisting of colloidal silica, fumed silica, ceria, alumina, titanium oxide, zirconia, manganese dioxide, polystyrene and poly(methylmethacrylate).

9. The method according to claim 1, wherein the abrasive particles are contained in the second chemical liquid at a concentration of 0.001 wt % to 10 wt %.

10. The method according to claim 1, wherein the second chemical liquid further comprises at least one selected from a group consisting of an oxidizing agent, an oxidation inhibitor, a surfactant and a pH adjustor.

11. A method for manufacturing a semiconductor device, comprising:
forming a polishing film above a semiconductor substrate; and
slide-contacting the polishing film with a polishing pad while feeding a first chemical liquid and a second chemical liquid to the polishing pad, thereby chemically mechanically polishing the polishing film, the first chemical liquid containing an electrolyte and bubbles having a diameter ranging from 10 nm to 1000 μm, the second chemical liquid containing abrasive particles.

12. The method according to claim 11, wherein the polishing film is formed of a metal selected from a group consisting of Cu, Al, W, Ti, Mo, Nb, Ta, V and Ru; a laminate film comprising the metal; a film formed of an alloy containing the metal; or a film formed of a nitride, boride or oxide of the metal.

13. The method according to claim 12, wherein the abrasive particles contained in the second chemical liquid are formed of colloidal silica or alumina.

14. The method according to claim 12, wherein the second chemical liquid further comprises at least one selected from a group consisting of an oxidizing agent, an oxidation inhibitor, a surfactant and a pH adjustor.

15. The method according to claim 11, wherein the polishing film is an SiO₂-based insulating film or an organic film.

16. The method according to claim 15, wherein the polishing film is an SiO₂-based insulating film and the abrasive particles contained in the second chemical liquid are ceria particles.

17. The method according to claim 15, wherein the polishing film is an organic film and the abrasive particles contained in the second chemical liquid are organic particles.

18. The method according to claim 15, wherein the second chemical liquid further comprises a surfactant.

19. The method according to claim 12, further comprising forming an underlying layer having a recess above the semiconductor substrate before forming the polishing film.

20. The method according to claim 19, wherein the underlying layer is formed of a low dielectric constant film.
